(19) United States
(12) Patent Application Publication
(10) Pub. No.: US 2025/0142719 A1
(43) Pub. Date: May 1, 2025

(54) FLEXIBLE CIRCUIT BOARD FOR CHIP INTEGRATION AND ELECTRONIC DEVICE HAVING THE SAME

(71) Applicant: Chipbond Technology Corporation, Hsinchu (TW)

(72) Inventors: Chiu-Hong Lai, Hsinchu (TW); Wen Ping Hsu, Hsinchu (TW); Yi Ling Hsieh, Hsinchu (TW); Dong-Sheng Li, Hsinchu (TW); Yi Ren Chian, Hsinchu (TW); San Lee, Hsinchu (TW); Pei-Ying Lee, Hsinchu (TW); Ting-Yi Kuo, Hsinchu (TW)

(21) Appl. No.: 18/909,469

(22) Filed: Oct. 8, 2024

(30) Foreign Application Priority Data
Oct. 31, 2023 (TW) 112141711
May 15, 2024 (TW) 113117866

(51) Int. Cl. H05K 1/02; H05K 1/09; H05K 1/18

(52) U.S. Cl. CPC H05K 1/0277; H05K 1/09; H05K 1/189

(57) ABSTRACT

A flexible circuit board designed for chip integration is provided. The flexible circuit board includes an insulating substrate, a conductive copper layer, a first tin layer, a second tin layer, and a first solder resist layer. The first tin layer has a first tin thickness, and the second tin layer has a greater second tin thickness. A first tin surface of the first tin layer and a second tin surface of the second tin layer are substantially level.

### BACKGROUND

The present disclosure relates to a flexible circuit board, and more particularly to a flexible circuit board for chip integration.

A flexible circuit board, which is bendable, is frequently used in electronic devices having a small space for chip integration. For example, as a reference, flexible tape-and-reel circuit board products manufactured by Chipbond Technology Corporation are applicable to various electronic devices such as flat displays, wearable devices, cell phones, tablet computers, laptop computers, in-vehicle displays, and industrial control panels.

A flexible circuit board is usually a film in the form of tape and reel. In the industry, a combination of a flexible circuit board and a chip has various names according to different production and installation modes, for example, a tape carrier package (TCP) or a chip-on-film (COF). Both TCP and COF utilize a flexible circuit board as a carrier for packaging a chip, and gold bumps on the chip and inner leads of copper patterned circuits located on the flexible circuit board are bonded by means of thermal compression.

In the prior art, in order to connect a flexible circuit board with gold bumps of a chip, the presence of a gold-tin eutectic is mandatory. The gold is provided by the gold bumps of the chip, and the tin is supplied by tin formed on surfaces of the inner leads and so a tin layer is plated on the surfaces of the inner leads. In addition to the inner leads, the copper patterned circuits further include conductive terminals such as outer leads for connecting to other electronic elements, and these terminals also usually include layers made by tin plating. Non-lead regions on the copper patterned circuit are additionally covered by solder resist for protection.

It should be noted that, as the space within an electronic device is continuously miniaturized, the degree of bending of a flexible circuit board becomes ever-increasing. Therefore, the bendability of a flexible circuit board needs to be ensured, that is, it needs to be ensured that patterned circuits do not become damaged by repeated bending or bending over an extended period of time. In a solution disclosed by Patent Reference 1 (CN 107006116 B), a dual solder resist layer structure is disposed above patterned circuits in a bendable region of a flexible circuit board to thereby alleviate the curvature of the bendable region, hence reducing physical stress experienced by the patterned circuits. Patent Reference 2 (CN 110121234 A) discloses a similar approach. In addition to providing a dual solder resist layer structure in a bendable region, a thin tin layer is further provided above the patterned circuits so as to comprehensively protect the patterned circuits. In parts, other than the bendable region, a thick tin layer is additionally provided to cover the thin tin layer. In addition to providing connections to a chip or other electronic elements, the thick tin layer also reinforces protective effects for the patterned circuits.

### SUMMARY OF THE INVENTION

With extensive research, it was discovered that the prior art above faces numerous issues in practice. For example, bending of Patent Reference 1 is hindered due to the increased thickness of the dual solder resist layer structure, and such issue is not adapted for the trend of constant miniaturization of the curvature of radius needed by current flexible circuit boards. In Patent Reference 2, the thin tin layer that is not covered by the thick tin layer forms apparent height differences from remaining parts of the thin tin layer covered by the thick tin layer on a surface of a flexible circuit board. It has been discovered that when a flexible circuit board is bent, stress can be easily accumulated at parts with height differences on a surface of a tin layer, which leads to cracking. Additionally, such height differences on a surface also add complications to subsequent processing.

In view of the above, a novel flexible circuit board is provided according to certain embodiments of the present disclosure. In a bendable region, a thin tin layer is disposed above patterned circuits (that is, the conductive copper layer), thereby protecting the conductive copper layer below from corrosion, collision or scratching as well as preventing reliability issues. It is further discovered, with extensive research, that a solder resist layer provides less satisfactory protection over a conductive copper layer than a tin layer does, so it remains necessary to protect a conductive copper layer by a tin layer. On the other hand, even though tin has greater hardness than copper, by providing a thinner tin layer in a bendable region, proper bendability and flexibility of a flexible circuit board can still be maintained. More particularly, in certain embodiments of the present disclosure, surfaces of a thin tin layer and a thick tin layer are level, that is, the two have the same height and have no substantial height difference, hence preventing the issue of stress accumulation.

A novel flexible circuit board is provided according to other embodiments. A thickness of copper of the patterned circuits (that is, a conductive copper layer) in a bendable region is greater and a thickness of copper of the patterned circuits (that is, the conductive copper layer) outside the bendable region is smaller. Thus, better ductility is provided via the copper having a greater thickness in the bendable region, thereby ensuring the bendability of the patterned circuits in the bendable region and preventing early damage caused by repeated bending or bending over an extended period of time.

According to certain embodiments of the present disclosure, a flexible circuit board for chip integration includes: an insulating substrate; a conductive copper layer, having a patterned circuit and located on the insulating substrate, the conductive copper layer having a first region and a second region electrically connected with each other; a first tin layer, located above the first region of the conductive copper layer, the first tin layer having a first tin thickness; a second tin layer, located above the second region of the conductive copper layer, the second tin layer having a second tin thickness; and a first solder resist layer, at least partially covering the first tin layer, wherein a first tin surface of the first tin layer is not in contact with the conductive copper layer and a second tin surface of the second tin layer is not in contact with the conductive copper layer are substantially level, wherein the first tin thickness is less than the second tin thickness.

According to other embodiments of the present disclosure, a flexible circuit board for chip integration includes: an insulating substrate; a conductive copper layer, having a patterned circuit located on the insulating substrate, the conductive copper layer having a first region and a second region electrically connected with each other, wherein the conductive copper layer located in the first region has a first copper thickness, the conductive copper layer located in the second region has a second copper thickness, and the first copper thickness is greater than the second copper thickness.

An electronic device is further provided according to certain embodiments of the present disclosure. The electronic device includes the flexible circuit board above and a chip, wherein the chip is disposed on the flexible circuit board.

### BRIEF DESCRIPTION OF THE DRAWINGS

FIG. 1 is a structural schematic diagram of a flexible circuit board according to a first embodiment of the present disclosure.

FIG. 2 is a structural schematic diagram of a flexible circuit board according to a second embodiment of the present disclosure.

FIG. 3A to FIG. 3D are structural schematic diagrams of flexible circuit boards according to other embodiments of the present disclosure.

FIG. 4 is a structural schematic diagram of a flexible circuit board according to yet another embodiment of the present disclosure.

FIG. 5 is a schematic diagram of an electronic device according to an embodiment of the present disclosure.

### DETAILED DESCRIPTION OF THE EMBODIMENTS

Embodiments of the present disclosure are described with reference to the accompanying drawings below. To prevent obscuring the content of the present disclosure, conventional elements, related materials, and related processing techniques are also omitted from the description below. Meanwhile, in order to clearly describe the present disclosure, the various elements in the accompanying drawings are not necessarily drawn to actual scales or relative ratios.

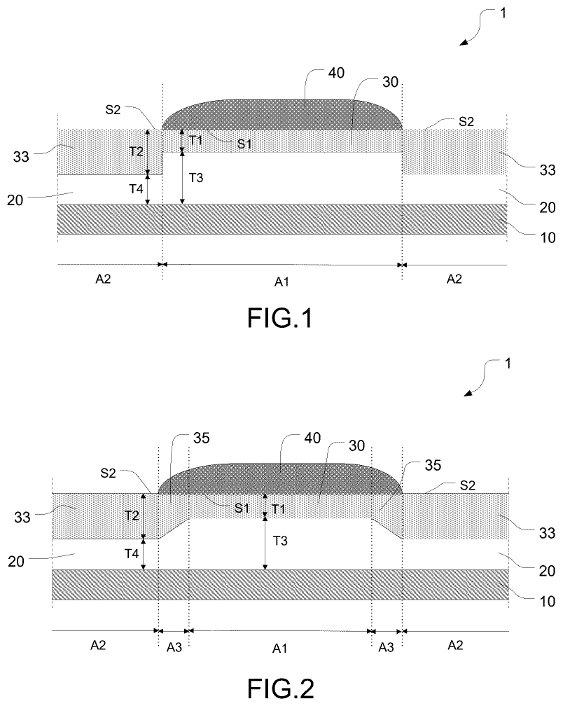

Referring to FIG. 1, a flexible circuit board 1 according to a first embodiment includes an insulating substrate 10, a conductive copper layer 20, a first tin layer 30, a second tin layer 33 and a solder resist layer 40.

The insulating substrate 10 is a substrate board, and the conductive copper layer 20 not yet patterned can be formed on the insulating substrate 10 by means of sputtering. The insulating substrate 10 can be implemented by a flexible, chemical-resistant and heat-resistant material, such as polyester, polyamide, or polyimide. A thickness of the insulating substrate 10 is generally between about 12 μm and about 85 μm or in another embodiment is between about 20 μm and about 50 μm. A thickness of the conductive copper layer 20 is, for example, between about 2 μm and 20 μm, or in another embodiment is between about 5 μm and 12 μm. An insulating substrate plated with a conductive copper layer can be generally referred to as a copper clad laminate (CCL), and reference can be made to commercially available CCL products such as S'PERFLEX or METALOYAL. Then, one or more patterned circuits are formed on the conductive copper layer 20 on the insulating substrate 10 by means of conventional lithography, with related details omitted herein.

As shown in FIG. 1, in this embodiment the conductive copper layer 20, having the patterned circuit, has a first region A1, and two second regions A2 respectively located on two sides of the first region A1. The conductive copper layer 20 located in the first region A1 and the conductive copper layer 20 located in the second region A2 are electrically connected with each other and may be electrically connected with the conductive copper layer 20 located in the first region A1 and the conductive copper layer 20 located in the second region A2 belong to a same circuit or a same wire. It should be noted that, in other embodiments, the numbers and positions of the first region A1 and the second region A2 can be varied and are not limited to the examples shown in FIG. 1.

The first region A1 of the conductive copper layer 20 is located in a bendable region of the flexible circuit board 1. The bendable region of the flexible circuit board 1 refers to a part having a measurable curvature when the flexible circuit board 1 is disposed in an electronic device and is bent. That is, the bendable region of the flexible circuit board 1 is a part that withstands substantial stress generated by bending. However, the first region A1 is not necessarily completely located within the bendable region of the flexible circuit board 1. In other embodiments, a range of the first region A1 can be greater than or smaller than the bendable region of the flexible circuit board 1. The first region A1 covers the part of the flexible circuit board 1 that withstands the greatest amount of stress when the flexible circuit board 1 is bent. In comparison, the second region A2 is usually located at a position at which bending is not needed, for example, a so-called lead region, that is, a position usually connectable to a chip (not shown) or various electronic elements (not shown); however, embodiments are not limited to the examples above.

Further as shown in FIG. 1, a first tin layer 30 is provided above the first region A1 of the conductive copper layer 20, and a second tin layer 33 is provided above the second region A2 of the conductive copper layer 20. The first tin layer 30 and the second tin layer 33 do not overlap each other, the first tin layer 30 has a thickness T1, and the second tin layer 33 has a thickness T2. In one embodiment, the thickness T1 is less than 0.2 μm, and in another embodiment less than or equal to 0.1 μm, for example, 0.03 μm, 0.05 μm or 0.08 μm. The thickness T2 can range between 0.2 μm and 2 μm, for example, 0.3 μm, 1 μm or 1.5 μm. In other embodiments, provided that the thickness T1 is less than the thickness T2, the values of the thicknesses T1 and T2 can be selected otherwise and are not limited to the values or ranges described above.

On the other hand, in this embodiment, a total thickness of the conductive copper layer 20 plus the first tin layer 30 or the second tin layer 33 is kept consistent. Thus, when the first region A1 of the conductive copper layer 20 has a thickness T3 and the second region A2 of the conductive copper layer 20 has a thickness T4, the thickness T3 is greater than the thickness T4 since the thickness T1 of the first tin layer 30 is less than the thickness T2 of the second tin layer 33.

It should be noted that the present disclosure is not limited to the examples above. In other words, in other embodiments, the feature of the thickness T1 being greater than the thickness T2 above and the feature of the thickness T3 being greater than the thickness T4 herein are not necessarily concurrently established, and the total thickness of the conductive copper layer 20 plus the first tin layer 30 or the second tin layer 33 is not necessarily kept consistent. In one embodiment, a difference between the thickness T3 and the thickness T4 can be between 0.1 μm and 1.9 μm, for example, 0.3 μm, 1 μm or 1.8 μm.

As shown in the drawing, the first tin layer 30 has a tin surface S1 (the upper surface) that is located opposite to a surface on which the first tin layer 30 is in contact with the conductive copper layer 20; similarly, the second tin layer 33 has a tin surface S2 (the upper surface) that is also located opposite to a surface on which the second tin layer 33 is in contact with the conductive copper layer 20. More particularly, in addition to satisfying the condition of the thickness T1 being less than the thickness T2, the tin surface S1 of the first tin layer 30 and the tin surface S2 of the second tin layer 33 are substantially at a same height and are level (or coplanar). That is to say, when observed from a surface of the flexible circuit board 1 opposite to the conductive copper layer 20 (that is, from the top of FIG. 1), even though the first tin layer 30 and the second tin layer 33 have different thicknesses, there is no significant height difference on the top. In one embodiment, even if observation is performed by using a scanning electron microscope (SEM) at a magnification of 300,000 times, the tin surface S1 and the tin surface S2 still appear level without significant height difference in between. It should be noted that, for a person of ordinary skill in the art of manufacturing of flexible circuit boards, surfaces of tin layers having undergone a same tin plating process are considered to be level. However, although the first tin layer 30 and the second tin layer 33 have undergone different tin plating processes and have a thickness difference, the tin surface S1 and the tin surface S2 have the same height and are still level, as the surfaces of tin layers having undergone a same tin plating process.

On the other hand, the thickness difference between the first tin layer 30 and the second tin layer 33 is buried below (that is, at an interface where the first tin layer 30 and the second tin layer 33 are in contact with the conductive copper layer 20) and is unexposed. In other words, respective horizontal ranges of the first tin layer 30 and the second tin layer 33 are determined from below and not from top. Thus, the first tin layer 30 and the second tin layer 33, although having different thicknesses, have upper surfaces at the same height and are thus together formed as a level surface, and this can reduce stress accumulation during bending, prevent non-uniform force received, and further prevent complications caused by different heights of surfaces in subsequent processing.

Moreover, the solder resist layer 40 covers the first tin layer 30. The solder resist layer 40 can be attached to the first tin layer 30 by means of adhesion bonding or printing. The solder resist layer 40 protects the conductive copper layer 20 from corrosion, collision, or scratching, and is also capable of alleviating sources of stress upon the conductive copper layer 20 during bending. In one embodiment, the solder resist layer 40 can further serve as a mask to form the second tin layer 33, and thus the solder resist layer 40 covers only the first tin layer 30 but does not cover the second tin layer 33. However, the present disclosure is not limited to the example above.

The solder resist layer 40 can be a cover layer (CL), or can be a material including components such as a solder resist agent, or can be formed by ink of a conventional type of epoxy resin (o-cresol novalac/phenol/DGEBA) or other suitable types of ink by means of screen printing. In one embodiment, a thickness of the solder resist layer 40 can range between 1 μm and 50 μm, for example, 40 μm or 50 μm.

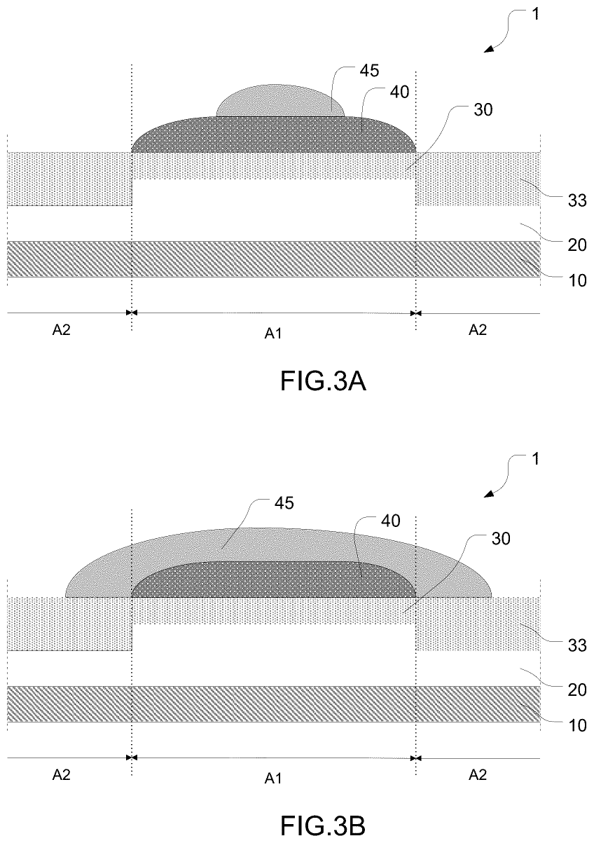

Next, as shown in FIG. 2, compared with the first embodiment shown in FIG. 1, the flexible circuit board 1 according to a second embodiment of the present disclosure primarily differs in that, the conductive copper layer 20 having the patterned circuit further has two third regions A3 respectively located between the first region A1 and the two second regions A2. The conductive copper layer 20 located in the third region A3 is electrically connected with the conductive copper layer 20 located in the first region A1 and the conductive copper layer 20 located in the second region A2, and may be electrically connected with the conductive copper layer 20 located in the third region A3, the conductive copper layer 20 located in the first region A1 and the conductive copper layer 20 located in the second region A2 belong to a same wire. It should be noted that, in other embodiments, the numbers and positions of the third region A3 can be varied and are not limited to the examples shown in FIG. 2.

Further as shown in FIG. 2, a third tin layer 35 is provided above the third region A3 of the conductive copper layer 20. The first tin layer 30, the third tin layer 35 and the second tin layer 33 are connected to but do not overlap one another, and upper surfaces thereof are coplanar. More particularly, a thickness of the third tin layer 35 is between the thickness T1 of the first tin layer 30 and the thickness T2 of the second tin layer 33. The thickness of the third tin layer 35 can gradually increase (or decrease) along a horizontal distance so as to serve as a buffer between the thickness T1 of the first tin layer 30 and the thickness T2 of the second tin layer 33, further preventing stress accumulation caused by a significant thickness difference during bending. On the other hand, in this embodiment, respective total thicknesses of the conductive copper layer 20 in the first region A1, the second region A2 and the third region A3 plus the first tin layer 30, the second tin layer 33 and the third tin layer 35 respectively are kept consistent. Thus, the thickness of the conductive copper layer 20 located in the third region A3 is between the thickness of the conductive copper layer 20 located in the first region A1 and the thickness of the conductive copper layer 20 located in the second region A2. Moreover, when the thickness of the third tin layer 35 can gradually increase (or decrease) along a horizontal distance, the thickness of the conductive copper layer 20 located in the third region A3 also correspondingly gradually decreases (or increases), and this is further conducive to reducing stress accumulation. However, the present disclosure is not limited to the example above. In other embodiments, respective total thicknesses of the conductive copper layer 20 in the first region A1, the second region A2 and the third region A3 plus the first tin layer 30, the second tin layer 33 and the third tin layer 35 respectively are not necessarily kept consistent. Moreover, the thickness of the third tin layer 35 or the thickness of the conductive copper layer 20 located in the third region A3 can gradually increase (or decrease) in a linear or non-linear manner, or can gradually increase (or decrease) in a stepped manner.

In one embodiment, a horizontal length of one single third region A3 can range between 5 μm and 200 μm, for example, can be 50 μm, 100 μm or 150 μm. The horizontal lengths of different third regions A3 are not necessarily the same.

In the embodiment shown in FIG. 2, the solder resist layer 40 concurrently covers the first tin layer 30 and the third tin layer 35; however, the present disclosure is not limited to the example above. In another embodiment, the solder resist layer 40 only needs to at least cover an interface between the first tin layer 30 and the third tin layer 35, but does not cover an interface between the second tin layer 33 and the third tin layer 35. In yet another embodiment (not shown), the solder resist layer 40 further covers the interface between the second tin layer 33 and the third tin layer 35.

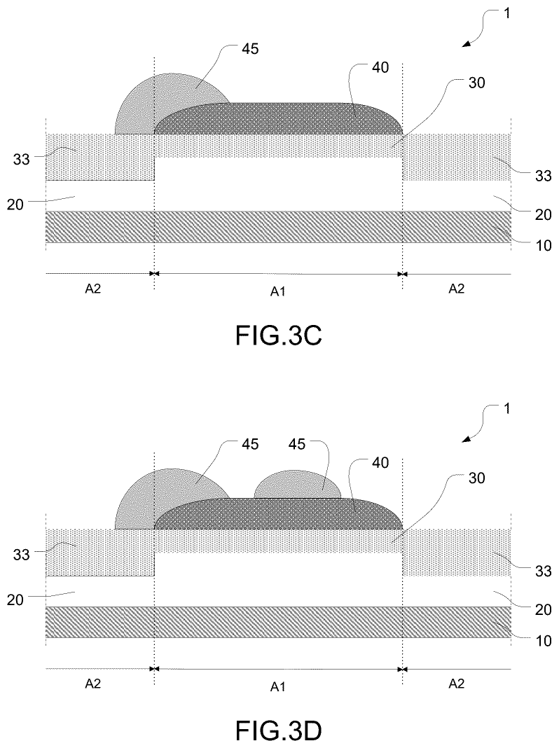

Next, referring to FIG. 3A to FIG. 3D, compared with the first embodiment shown in FIG. 1, the flexible circuit boards 1 according to other embodiments of the present disclosure primarily differ in that, the flexible circuit boards 1 further include a solder resist layer 45 formed on the solder resist layer 40 and/or the second tin layer 33. The solder resist layer 45 can be implemented by a material the same as or different from the solder resist layer 40.

More specifically, in the embodiment in FIG. 3A, the solder resist layer 45 covers only a part of the solder resist layer 40 but does not cover the second tin layer 33. The approach above further reinforces the bendability in the bendable region of the flexible circuit board 1 by protection provided by a small part of the solder resist layer 45.

Optionally, in the embodiment in FIG. 3B, the solder resist layer 45 covers an entirety of the solder resist layer 40, and further covers a part of the second tin layer 33. In addition to enhancing the advantage of the embodiment in FIG. 3A, since the entirety of the solder resist layer 40 is covered, the approach of the embodiment in FIG. 3B further prevents the solder resist layer 40 from stripping off from the first tin layer 30 during subsequent processing.

Optionally, in the embodiment in FIG. 3C, compared with FIG. 3B, the solder resist layer 45 covers only a part (but not an entirety) of the solder resist layer 40, but at the same time covers a part of the second tin layer 33, and more particularly, covers the interface between the solder resist layer 40 and the second tin layer 33. In addition to preventing the solder resist layer 40 located on an edge from stripping off from the first tin layer 30 during subsequent processing, the approach above further prevents an excessive amount of solder resist layer 45 from remaining on the solder resist layer 40, wherein an overly large thickness caused by such excessive amount of solder resist layer 45 can cause bending difficulties of the flexible circuit board 1.

Optionally, in the embodiment in FIG. 3D, a part of the solder resist layer 45 covers the intersection between the solder resist layer 40 and the second tin layer 33 as in FIG. 3C, and another part of the solder resist layer 45 covers only a part of the solder resist layer 40 but does not cover the second tin layer 33 as in FIG. 3A. The approach above consolidates the advantages of FIG. 3A and FIG. 3C.

Moreover, in an embodiment which is not shown, the solder resist layer 45 covers only a part of the second tin layer 33 but does not cover the solder resist layer 40, and can be kept at a distance from the solder resist layer 40 or can be closely adjacent to the solder resist layer 40.

In yet another embodiment which is not shown, an area of the solder resist layer 45 on the flexible circuit board 1 occupies 10% or more of an area of the solder resist layer 40 on the flexible circuit board 1. However, the present disclosure is not limited to the example above.

It should be noted that, the various implementation forms of the solder resist layer 40 and the solder resist layer 45 shown in FIG. 3A to FIG. 3D are also applicable to the embodiment in FIG. 2 (that is, a situation where the third region A3 is used as a buffer region).

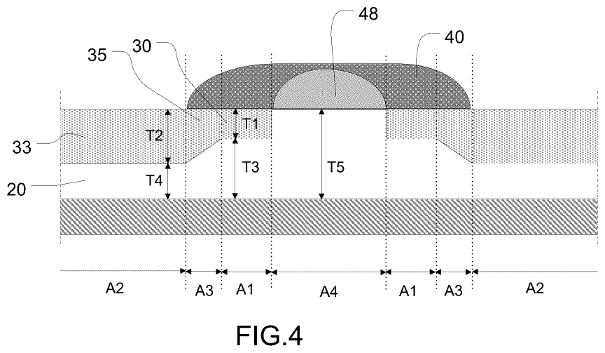

Next, as shown in FIG. 4, compared with the first embodiment shown in FIG. 1 and the second embodiment shown in FIG. 2, the flexible circuit board 1 according to another embodiment of the present disclosure primarily differs in that, the conductive copper layer 20 having the patterned circuit further has a fourth region A4 such that both of the first region A1 and the third region A3 are located between the fourth region A4 and the second region A2. The conductive copper layer 20 located in the fourth region A4 is electrically connected with the conductive copper layer 20 located in the first region A1, the conductive copper layer 20 located in the third region A3 and the conductive copper layer 20 located in the second region A2, and may be electrically connected with the conductive copper layer 20 located in the fourth region A4, the conductive copper layer 20 located in the first region A1, the conductive copper layer 20 located in the third region A3 and the conductive copper layer 20 located in the second region A2 belong to a same circuit or a same wire. It should be noted that, in other embodiments, the third region A3 in FIG. 4 can also be omitted, and the present disclosure is not limited to the example shown in FIG. 4.

Further as shown in FIG. 4, compared with tin layers provided above the conductive copper layer 20 in all of the first region A1, the second region A2 and the third region A3, no tin layer is provided above the conductive copper layer 20 located in the fourth region A4, but the conductive copper layer 20 is directly covered by a solder resist layer 48. Meanwhile, a thickness T5 of the conductive copper layer 20 located in the fourth region A4 is also greater than the thicknesses of the conductive copper layer 20 in the first region A1, the second region A2 and the third region A3. Moreover, the upper surface of the conductive copper layer 20 in the fourth region A4 may be coplanar with the upper surfaces of the first tin layer 30, the third tin layer 35 and the second tin layer 33.

The fourth region A4 of the conductive copper layer 20 is located in a bendable region of the flexible circuit board 1. A range of the fourth region A4 can be greater than or smaller than the bendable region of the flexible circuit board 1. The fourth region A4 covers the part of the flexible circuit board 1 that withstands the greatest amount of stress when the flexible circuit board 1 is bent. Although the solder resist layer 48 has less protection over the conductive copper layer 20 than a tin layer, since no tin layer is provided above the fourth region A4 (and just a thin tin layer is provided above the first region A1), the bendability and flexibility of the flexible circuit board 1 can be increased (that is, the flexible circuit board 1 is more easily bendable), such that the flexible circuit board 1 can be better adapted to smaller spaces. Moreover, with the greater thickness T5 (and the thickness T3) of the conductive copper layer 20, the bendability of the patterned circuits in the bendable region is also increased, hence preventing wire breakage caused by bending of the flexible circuit board 1.

In one embodiment, the solder resist layer 48 can further serve as a mask to form the first tin layer 30, and thus the solder resist layer 48 covers only the conductive copper layer 20 in the fourth region A4 but does not cover the first tin layer 30. However, the present disclosure is not limited to the example above. Moreover, the solder resist layer 48 can be implemented by a material the same as or different from the solder resist layer 40.

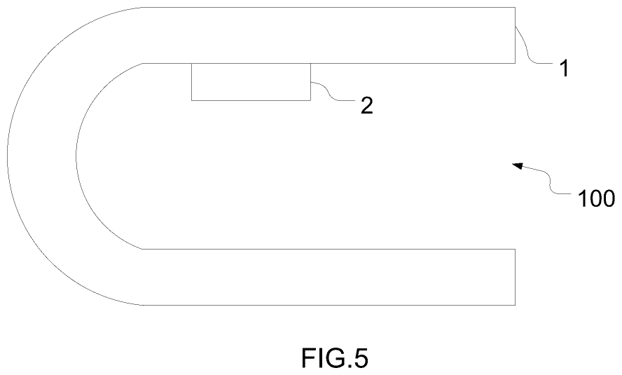

FIG. 5 shows an electronic device 100 according to another embodiment of the present disclosure. The electronic device 100 includes the flexible circuit board 1, and a chip 2 disposed on the flexible circuit board 1. Regarding details of the flexible circuit board 1, please refer to the description in conjunction with FIG. 1 to FIG. 4 above. The electronic device 100 can be, for example, a flat display, a wearable device, a cell phone, a tablet computer, a laptop computer, an in-vehicle display, or an industrial control panel, and the chip 2 can be, for example, a chip for driving image display. As shown in FIG. 5, due to the small space within the electronic device 100, the flexible circuit board 1 is inevitably bent for usage therein. Associated details are well-known to a person of ordinary skill in the art and are thus omitted herein. Moreover, in an embodiment which is not shown, the electronic device 100 is not necessarily a product for immediate use of an end user, and can be a semi-finished product in need of subsequent processing as long as the chip 2 is already disposed on the flexible circuit board 1.

The description above provides merely several embodiments of the present disclosure and are not to be construed as limitations to the scope of the claims of the present disclosure. All equivalent changes or modifications completed without departing from the spirit disclosed by the several embodiments are all encompassed within the scope of the appended claims.

What is claimed is:

1. A flexible circuit board for chip integration, comprising:
an insulating substrate;
a conductive copper layer, having a patterned circuit and located on the insulating substrate, the conductive copper layer having a first region and a second region electrically connected with each other;
a first tin layer, located above the first region of the conductive copper layer, the first tin layer having a first tin thickness; and
a second tin layer, located above the second region of the conductive copper layer, the second tin layer having a second tin thickness;
wherein the first tin layer has a first tin surface opposite to and not in contact with the conductive copper layer, the second tin layer has a second tin surface opposite to and not in contact with the conductive copper layer, and the first tin surface and the second tin surface are substantially level,
wherein the first tin thickness is less than the second tin thickness.

2. The flexible circuit board according to claim 1, wherein the conductive copper layer further has a third region, the third region is located between the first region and the second region and is electrically connected with the first region and the second region, the flexible circuit board further comprises a third tin layer, the third tin layer is located above the third region of the conductive copper layer, and the third tin layer has a third tin thickness between the first tin thickness and the second tin thickness.

3. The flexible circuit board according to claim 1, wherein the conductive copper layer located in the first region has a first copper thickness, the conductive copper layer located in the second region has a second copper thickness, and the first copper thickness is greater than the second copper thickness.

4. The flexible circuit board according to claim 3, wherein the conductive copper layer further has a third region, the third region is located between the first region and the second region, and a thickness of the conductive copper layer located in the third region is between the first copper thickness and the second copper thickness.

5. The flexible circuit board according to claim 3, wherein the conductive copper layer further has a fourth region, the first region is located between the fourth region and the second region, the fourth region is electrically connected with the first region and the second region, and a thickness of the conductive copper layer located in the fourth region is greater than the first copper thickness.

6. The flexible circuit board according to claim 5, further comprising:
a first solder resist layer, at least partially covering the first tin layer; and
a second solder resist layer, at least partially covering the fourth region of the conductive copper layer, wherein no tin layer is present between the fourth region of the conductive copper layer and the second solder resist layer.

7. The flexible circuit board according to claim 1, wherein the first region is located in a bendable region of the flexible circuit board.

8. The flexible circuit board according to claim 1, further comprising a first solder resist layer at least partially covering the first tin layer, wherein the first solder resist layer does not cover the second tin layer, and a thickness of the first solder resist layer ranges between 1 μm and 50 μm.

9. The flexible circuit board according to claim 8, further comprising a third solder resist layer at least partially covering the first solder resist layer and/or the second tin layer.

10. A flexible circuit board for chip integration, comprising:
an insulating substrate;
a conductive copper layer, having a patterned circuit and located on the insulating substrate, the conductive copper layer having a thickness ranging between 2 μm and 20 μm, the conductive copper layer having a first region and a second region electrically connected with each other, wherein the conductive copper layer located in the first region has a first copper thickness, the conductive copper layer located in the second region has a second copper thickness, and the first copper thickness is greater than the second copper thickness.

11. The flexible circuit board according to claim 10, wherein the conductive copper layer further has a third region, the third region is located between the first region and the second region, and a thickness of the conductive copper layer located in the third region is between the first copper thickness and the second copper thickness.

12. The flexible circuit board according to claim 10, wherein the conductive copper layer further has a fourth region, the first region is located between the fourth region and the second region, the fourth region is electrically connected with the first region and the second region, and a thickness of the conductive copper layer located in the fourth region is greater than the first copper thickness.

13. The flexible circuit board according to claim 12, further comprising:
a first tin layer, located above the first region of the conductive copper layer;
a first solder resist layer, at least partially covering the first tin layer; and
a second solder resist layer, at least partially covering the fourth region of the conductive copper layer, wherein no tin layer is present between the fourth region of the conductive copper layer and the second solder resist layer.

14. The flexible circuit board according to claim 10, further comprising:
a first tin layer, located above the first region of the conductive copper layer;
a second tin layer, located above the second region of the conductive copper layer; and
a first solder resist layer, at least partially covering the first tin layer.

15. The flexible circuit board according to claim 14, wherein the first tin layer has a first tin thickness, the second tin layer has a second tin thickness, and the first tin thickness is different from the second tin thickness.

16. The flexible circuit board according to claim 10, wherein the first region is located in a bendable region of the flexible circuit board.

17. An electronic device, comprising:
the flexible circuit board according to claim 1; and
a chip, disposed on the flexible circuit board.
